(19) United States
(12) Patent Application Publication
(10) Pub. No.: US 2013/0045360 A1
(43) Pub. Date: Feb. 21, 2013

(54) SURFACE MODIFICATION OF IMPLANT DEVICES

(71) Applicants: Rolando Arturo Gittens Ibacache, Atlanta, GA (US); Kenneth H. Sandhage, Roswell, GA (US); Rina Tannenbaum, Smyrna, GA (US); Zvi Schwartz, Atlanta, GA (US); Barbara D. Boyan, Atlanta, GA (US)

(72) Inventors: Rolando Arturo Gittens Ibacache, Atlanta, GA (US); Kenneth H. Sandhage, Roswell, GA (US); Rina Tannenbaum, Smyrna, GA (US); Zvi Schwartz, Atlanta, GA (US); Barbara D. Boyan, Atlanta, GA (US)

(73) Assignee: Georgia Tech Research Corporation, Atlanta, GA (US)

(21) Appl. No.: 13/575,540

(22) PCT Filed: Jan. 28, 2011
(86) PCT No.: PCT/US11/23011

§ 371 Date: Oct. 16, 2012

Related U.S. Application Data
(60) Provisional application No. 61/299,433, filed on Jan. 29, 2010.

(51) Int. Cl. C23C 8/08; C23C 8/20; B32B 3/30; C23C 16/06; C23C 8/02; C23C 8/10; C23C 8/24

(52) U.S. Cl. 428/141; 148/240; 148/284; 148/283; 148/206; 148/238; 148/281; 427/2.24

(57) ABSTRACT

Provided according to embodiments of the invention are methods of manufacturing implant devices. In methods described herein, implant devices are exposed to a reactive gas that includes a reactive species, and optionally, an inert gas, at elevated temperatures, for a duration sufficient to generate a high density of nanoscale structures on the exposed surface of the device. Also provided are implant devices formed by methods described herein.

### CROSS-REFERENCE TO RELATED APPLICATIONS

This application claims priority from U.S. Provisional Application Ser. No. 61/299,433, filed on Jan. 29, 2009, the disclosure of which is hereby incorporated by reference herein in its entirety.

### FIELD OF THE INVENTION

The present invention relates to surface modification techniques and, more particularly, to surface modification techniques for biomaterials.

### BACKGROUND

Integration of metallic and ceramic implants with the surrounding bone is critical for successful bone regeneration and healing in dental and orthopedic applications. The desire to accelerate and improve osseointegration drives many implantology research and development efforts, particularly for patients whose bones have been compromised by disease or age. Previous work has shown that the surface characteristics of implants have a direct influence on tissue response by affecting protein adsorption and by modulating cell proliferation and differentiation. Surface characteristics such as roughness, chemistry and energy have been reported to significantly influence cell differentiation, local factor production and consequently, bone growth and osseointegration.

Surface modification strategies for metallic implants to improve osseointegration have attempted to mimic the characteristics of bone. During bone remodeling, previously-formed bone is resorbed by osteoclasts, in part to remove micro-cracks before new bone is formed in these primed regions. Resorption lacunae left by osteoclasts, created through acidification and proteinase activity, have a distinct hierarchical structural complexity. Resorption lacunae consist of microscale pits (up to 100 μm in diameter and 50 μm in depth) with submicro-scale roughness formed by the irregular acid-etching at the ruffled border of the osteoclast and nanoscale features created by the collagen fibers left on the surface.

Studies have shown that increases in surface micro- and submicro-scale roughness, with feature sizes comparable to those of resorption pits and cell dimensions, may lead to enhanced osteoblast differentiation and local factor production in vitro, increased bone-to-implant contact in vivo and improved clinical rates of wound healing. Surface nanoscale roughness, which directly corresponds to the sizes of proteins and cell membrane receptors, may also play an important role in osteoblast differentiation and tissue regeneration.

The literature on the effect of nanoscale surface roughness in osteoblast response has been dominated by studies on the initial interactions between osteoblasts and nano-modified polymeric substrates, and such work has indicated that nanoscale roughness can significantly affect cell adhesion, proliferation, and spreading. Similar results have been found for ceramic and metallic substrates. However, other studies report either a decrease in osteoblast proliferation with an increase in nanoscale roughness, or no effect of nanoscale roughness on proliferation in the absence of microscale surface roughness.

Relatively few studies have examined the effects of nanostructured surfaces on osteoblast differentiation. Some reports have indicated that increased osteoblast proliferation on nanostructured surfaces coincided with an increase in alkaline phosphatase (ALP) synthesis, increased Ca-containing mineral deposition, and higher immunostaining of osteocalcin (OCN) and osteopontin. Gene expression studies have shown an increase in the expression of RUNX2, osterix (OSX), and bone sialoprotein (BSP) in osteoblasts grown on nano-roughened surfaces. Other studies examined the protein levels of particular differentiation markers and local factors, and reported an increase in differentiation, and an increase in factors PGE₂ and active TGF-β1, when submicro- to nanoscale roughness was introduced to micro-rough substrates.

More recent studies have focused on the hierarchical combination of both micro- and nanoscale roughness to promote osseointegration on clinically-relevant surfaces. Although some of these studies have reported promising results of increased osteoblast proliferation and differentiation, it has been challenging to create a tailored hierarchical surface without altering other underlying characteristics of the substrate (particularly the microscale roughness and surface chemistry). For this reason, it has been difficult to decouple the effects of nanoscale features from those of other surface features, such as surface micro-roughness, surface chemistry, and/or surface energy.

Therefore, methods of forming tailored hierarchical features, particularly on metallic and ceramic materials, would be desirable.

### SUMMARY

Provided according to some embodiments of the invention are methods of manufacturing an implant device that include exposing a surface of the implant device to a reactive gas at a temperature in a range of 500 to 1000° C., wherein the reactive gas includes a reactive species and, optionally, an inert gas, for a duration sufficient to generate a high density of nanoscale structures on the exposed surface of the device.

In some embodiments of the invention, the mean peak to valley height of the nanoscale structures is in a range of 70 to 500 nm. Further, in some embodiments, the density of the nanoscale structures is in a range of 1 to 1000 structures per square micrometer. In some embodiments, the implant device includes nanostructures having a diameter in a range of 20 to 500 nm and a height in a range of 60 to 800 nm.

In some embodiments of the invention, the reactive species comprises oxygen, hydrogen, nitrogen, sulfur and/or carbon. Further, in some embodiments, the reactive species is present in the reactive gas at a partial pressure in a range of 7×10⁻⁶⁴ to 1 atm.

In some embodiments of the invention, the surface of the implant device is pre-treated prior to exposure to the reactive gas, and in some embodiments, the implant device is pre-treated by sand blasting, grit blasting, acid etching and/or machining.

In some embodiments of the invention, the implant device is a metallic implant device and the reactive species is oxygen gas. In some embodiments, the metallic implant device includes titanium metal and/or a titanium alloy. In some embodiments, the implant device includes a ceramic implant device and the reactive species is hydrogen gas.

Also provided according to embodiments of the invention are implant devices formed by the method described herein. In some embodiments, the implant devices include microscale structures on a surface of the device, wherein the microscale structures have diameters in a range of 1 and 100 μm and heights in a range of 1 to 50 μm; and nanoscale structures on the surface of the device, wherein the nanoscale structures have diameters in a range of 20 to 500 nm and heights in a range of 60 to 800 nm. In some embodiments, the implant devices have a density of the nanoscale structures in a range of 4 to 50 structures per square micrometer. Further, in some embodiments, the valley to peak ratio of the implant devices is in a range of 70 to 500 nm.

### BRIEF DESCRIPTION OF THE DRAWINGS

FIGS. 1a-1f show NM-treatment of (a) PT surfaces via oxidation in flowing synthetic air (21% O₂, 79% N₂) at 740° C. for times of: (b) 45 minutes; (c) 90 minutes; (d) 180 minutes. The modification process introduced: (b) nanoscale protuberances with low surface coverage after 45 minutes; (c) a relatively high density of nanostructures after 90 minutes; and (d) coarse structures after 180 minutes. These SEM images are representative of the entire PT Ti disk surfaces. (e, f) Image analyses of SEM images revealing the distribution of diameters of the nanoscale structures formed after 45 minutes and 90 minutes, respectively.

FIGS. 2a-2f provide SEM images of starting SLA samples (a, c, e), and of NMSLA samples (b, d, f) generated via oxidation in flowing synthetic air at 740° C. for 90 minutes. These images indicate that the NM process yielded a relatively high density of nanoscale structures over the entire specimen surface and did not appreciably affect the overall microscale roughness of the SLA surface.

FIGS. 3a-3d provide SEM images of the surfaced of (a) PT, (b) NMPT, (c) SLA, and (d) NMSLA samples used for further surface characterization and for cell experiments. The NM treatment consisted of oxidation in flowing synthetic air for 90 min at 740° C.

FIGS. 4a-4c provide surface characterization data of the NM-treated samples, which were oxidized in flowing synthetic air for 90 min at 740° C., and their controls. (a-d) Optical images of water contact angles on PT, SLA, NMPT, and NMSLA surfaces. The contact angles measured for PT and NMPT samples were similar and smaller than for the SLA and NMSLA samples. (e) X-ray diffraction (XRD) patterns obtained from PT, SLA, NMPT, and NMSLA samples. (f) TEM image of an ion-milled cross-section of a NMPT specimen revealing the compact and conformal oxide layer formed after NM treatment. The average thickness of this oxide scale was 1.2 μm. (g) Selective area electron diffraction pattern obtained from the oxide scale, which was consistent with pure rutile TiO₂.

FIGS. 5a-5e show effects of nanoscale surface features and microscale surface roughness on osteoblast differentiation. MG63 cells were plated on PT, NMPT, SLA, and NMSLA surfaces and grown to confluence. The NM treatment consisted of oxidation in flowing synthetic air for 90 min at 740° C. At confluence, (a) DNA content, (b) ALP specific activity, (c) OCN, (d) OPG, and (e) VEGF levels were measured. Data represented are the mean±SE of six independent samples. * refers to a statistically-significant p value below 0.05 vs. PT; # refers to a statistically-significant p value below 0.05 vs. NMPT; $ refers to a statistically-significant p value below 0.05 vs. SLA.

FIGS. 6a-6d shows SEM images of PT titanium samples (a) that were relatively smooth (Ra<0.5 μm) were exposed to a gas mixture of 99.999% N₂/0.001% O₂ for 8 hours at various temperatures: 690° C. (b), 740° C. (c) and 840° C. (d).

FIGS. 7a-7d show SEM images that were used to evaluate the similarities and differences between PTG4 and NMPTG4 samples. At low magnifications, the surface of the original PTG4 samples was relatively smooth with no distinct features except for some apparent grain boundaries and several holes that looked like missing grains (a). The surfaces of all the NMPTG4 samples were very similar to the original PTG4 sample, with the holes left by missing grains still evident (b, c, d).

FIGS. 8a-8d shows that at mid-magnifications, the NMPTG4-45m sample (b) had higher surface coverage of nano-structures than the rest of the NMPTG4 modified for 90 (c) and 180 minutes (d), which had shallower holes and the presence of bigger structures possibly resulting from the coalescence of the nano-structures after prolonged modification times.

FIGS. 9a-9d show the samples of FIGS. 8 and 9 at higher magnifications. The nano-structures on the NMPTG4-45m sample were found to be in the size range of 20 to 150 nm in diameter and 10 to 300 nm in height (b).

FIGS. 10a-10d show images of the surfaces, acquired by scanning electron microscopy (SEM), that reveal the different topographies of an alloy sample. The rTiAlV surface presented 100-300 μm craters with superimposed micron-scale features (a). All the nano-modified surfaces maintained a similar macro- to micro-scale structure (b, c, d).

FIGS. 11a-11d show the surfaces in FIG. 10 at higher magnification. In the case of the rTiAlV sample the micron scale features resembled small terraces with faint submicron-scale texture (a). However, the SEM images of the nano-modified surfaces also revealed an additional nano-texture that homogeneously covered the entire surface (b, c, d).

FIGS. 12a-12d show the surface of FIGS. 10 and 11 at very high magnifications. Again the rTiAlV sample showed no distinct features except for some minor ridges and dips on the surface (a). At this magnification, a difference could be distinguished between the different modification times. The NMrTiAlV-45m sample had very well defined nano-structures with a size of 20 to 150 nm in diameter and 10 to 300 nm in height (b). However, although samples modified for 90 (c) and 180 minutes (d) had similar nano-structures, these started coalescing and forming bigger aggregates.

### DETAILED DESCRIPTION OF EMBODIMENTS OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that, when used in this specification, the terms “comprises” and/or “including” and derivatives thereof, specify the presence of stated features, operations, elements, and/or components, but do not preclude the presence or addition of one or more other features, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions and/or layers, these elements, components, regions and/or layers should not be limited by these terms. These terms are only used to distinguish one element, component, region or layer from another element, component, region or layer. Thus, a first element, component, region or layer discussed below could be termed a second element, component, region or layer without departing from the teachings of the present invention.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

In the drawings and specification, there have been disclosed embodiments of the invention and, although specific terms are employed, they are used in a generic and descriptive sense only and not for purposes of limitation, the scope of the invention being set forth in the following claims.

### Nanoscale Modification of Implant Devices

Provided according to embodiments of the invention are methods of manufacturing implant devices. In some embodiments of the invention, metallic and/or ceramic implant devices are exposed to a gas that includes a reactive species, and optionally, an inert gas, at elevated temperatures, for a duration sufficient to generate nanoscale structures on the exposed surface of the device.

### Implant Devices

As used herein, an “implant” refers to a device that is inserted into the body of an avian or mammalian subject. Mammals of the present invention include, but are not limited to, humans, canines, felines, bovines, caprines, equines, ovines, porcines, rodents (e.g. rats and mice), lagomorphs, primates, and the like, and mammals in utero.

Any suitable implant device may be used in embodiments of the invention. Non-limiting examples of biomedical or surgical implants that may be used according to some embodiments of the invention include dental implants such as endosteal, ramus frame, subperiosteal and intramucosal implants; orthopedic implants such as hip, knee, elbow and shoulder implants, including nails, wires, pins, screws, plates, hip prostheses, ACL/PCL reconstructive implants, mini-fragment implants, small fragment implants, and large fragment implants; craniomaxillofacial implants; spinal implant components and devices including articulating components; prosthetic and transcutaneous devices that require direct skeletal attachment; and cardiovascular components and devices such as wires, cables, and stents.

Implants according to embodiments of the invention include metallic and/or ceramic materials. As such, in some embodiments, the implant only includes metallic or ceramic materials, and in some embodiments, the implant may include both metallic and ceramic portions. In some embodiments, implants may include other materials, such as other inorganic materials and organic materials such as polymers. Any suitable portion of the implant may be metallic and/or ceramic. In some embodiments, the implant is completely or essentially all metallic and/or ceramic. In some embodiments of the invention, the implant has a total metallic and/or ceramic content (total content=metallic+ceramic content) greater than 1 wt. %, 5 wt. %, 10 wt. %, 15 wt. %, 20 wt. %, 30 wt. %, 40 wt. %, 50 wt. %, 60 wt. %, 70 wt. %, 80 wt. %, 90 wt. % 95 wt. % or 99% wt. %.

### Metallic Implants

Metallic implants include those made of pure metal and/or metal alloys. Any suitable metal may be used in embodiments of the invention. Examples of metals include titanium, tantalum, niobium, molybdenum, magnesium and zirconium. Any suitable metal alloy may used in embodiments of the invention. As used herein, the term “alloy” includes solid solutions, mixtures and combinations thereof. Non-limiting examples of alloys are shown in Table 1 below.

TABLE 1

| Alloy Class | Examples |
|---|---|
| Iron (Fe) alloys | 316L stainless steel |
| | Fe—Al—Mn |
| | Fe—Al—Mn—C—Cr |
| Cobalt chromium (Co—Cr) | Co—Cr—Mo (vitallium) |
| alloys | |
| Tantalum (Ta) | cpTa |
| Titanium (Ti) alloys | cpTi |
| | Ti—0.5Pt |
| | TI—6Al—4V |
| | Ti—6Al—4V—0.5Pt |
| | Ti—6Al—7Nb |
| | Ti—6Al—7Nb—0.5Pt |
| | Ti—5Al—1.5B |
| | Ti—5Al—2.5Fe |
| | Ti—4.2Fe—6.9Cr (TFC) |
| | Ti—4.2Fe—6.7Cr—3Al (TFCA) |
| | Ti—35Nb—7Zr—5Nb |
| | Ti—35Nb—7Zr—5Ta (TNZT) |
| | Ti—35Nb—7Zr—5Ta—0.4O (TNZTO) |
| | Ti—29Nb—13Ta—7.1Zr |
| | Ti—29Nb—13Ta—2Sn |
| | Ti—29Nb—13Ta—4.5Zr |
| | Ti—29Nb—13Ta—4.6Sn |
| | Ti—29Nb—13Ta—6Sn |
| | Ti—29Nb—13Ta—4Mo |
| | Ti—29Nb—13Ta—4.6Zr (aged) |
| | Ti—16Nb—13Ta—4Mo |
| | Ti—15Mo—5Zr—3Al (ST) aged |
| | Ti—15Mo—3Nb—3O (ST) aged |
| | Ti—13Nb—13Zr |
| | Ti—12Mo—6Zr—2Fe (TMZF) |
| | Ti—Mo |
| | Ti—Ta |
| | NiTi (Nitinol) |
| Magnesium (Mg) alloys | Mg |
| | Mg—Al |

Ceramic Implants

Any suitable ceramic may be used in embodiments of the invention. Non-limiting examples of ceramics include titanium dioxide, zirconia (ZrO₂), alumina (Al₂O₃), barium titanate (BaTiO₃), calcium phosphate-based ceramics (e.g., hydroxyapatite) and lead-based piezoceramics (e.g., Pb(Ti,Zr)O₃).

### The Reactive Gas

Any suitable concentration of the reactive gas may be used in embodiments of the invention. In some embodiments, the reactive species is present at a partial pressure of 0.1 atm to 1 atm, in some embodiments, at a partial pressure in a range of 1×10⁻⁶ atm to 1 atm, in some embodiments at a partial pressure in a range of 3×10³⁵ atm to 1 atm, and in some embodiments, in a range of 7×10⁻⁶⁴ atm to 1 atm.

The reactive gas includes at least one reactive species. Any suitable reactive species may be included in the reactive gas. However, in some embodiments, the reactive species includes oxygen, hydrogen, nitrogen, sulfur and/or carbon, and other elements may be in present in combination with these elements to form the reactive species. Non-limiting examples of reactive species include oxygen, hydrogen, carbon dioxide, nitric oxide and sulfur dioxide. Mixtures of different reactive species may also be used.

In some embodiments, the reactive gas includes an inert gas. Any suitable inert gas may be included in the reactive gas. Non-limiting examples of inert gases include argon, helium or neon. Mixtures of inert gases may also be used. Any suitable concentration of inert gas may be used.

An implant device according to an embodiment of the invention may be exposed to the reactive gas in a batch, continuous or semi-continuous reactor. In addition, the reactive gas may be exposed to the implant in an open system. In some embodiments, the reactive gas has a flow rate in a range of 100 to 2000 standard milliliters per minute. The entire device or only a portion of the device may be exposed to the reactive gas.

### Temperatures

In some embodiments of the invention, the implant device is exposed to the reactive gas at a temperature in a range of 500 to 1000° C. In particular embodiments, the implant device is exposed to the reactive gas at a temperature in a range of 650 to 800° C.

The duration of the exposure to the reactive gas may play a role in the nanoscale modification of the surface. As such, in some embodiments, the implant device is exposed to the reactive gas for a time in a range of 0.25 to 8 hours. In particular embodiments, the implant device is exposed to the reactive gas at a temperature in a range of 650 to 800° C., and the implant device is exposed to the reactive gas for a time in a range of 0.25 to 3 hours.

### Pre-Treatment of the Implant Surface

In some embodiments of the invention, the metallic and/or ceramic implant may be pretreated prior to exposure to the reactive gas. For example, in some embodiments, an oxide from the surface of a metal implant may be removed prior to exposing the implant to the reactive gas. In some embodiments, the surface of the implant may be treated by sand blasting, grit blasting, acid etching and/or machining. Pre-treatment may also include cleaning, for example, with an organic solvent, detergent and/or water, by rinsing or using an ultra-sonication device. Any suitable pre-treatment of the implant devices may be used, and methods of pre-treating such surface are known to those in the art. Some of the pretreatments may create microscale features in the range of 0.5 to 10 μm, 10 to 30 μm, 30 to 100 μm, or 100 to 500 μm. In some embodiments, the pretreatments may also give the surface an average roughness (Sₐ) in the range of 0.1 to 5 μm.

### The Nanoscale Modified (NM) Implant Devices

In some embodiments of the invention, provided are implant devices that include nano- and micro-scale structures. As used herein, nanoscale structures are defined as structures sized 1 to 1000 nanometers in at least one of its dimensions; and microscale structures includes structures sized 1 to 100 micrometers. In some embodiments, provided are implants that have micro-scale structures having a diameter in a range of 1 and 100 μm and a height in a range of 1 to 50 μm. In some embodiments, the implants have nanoscale structures having a diameter in a range of 20 to 500 nm and a height in a range of 60 to 800 nm. In some embodiments, the implants have both microscale structures having a diameter in a range of 1 and 100 μm and a height in a range of 1 to 50 μM and nano-scale structures having a diameter in a range of 20 to 500 nm and a height in a range of 60 to 800 nm. The terms “microscale strucures” and “nano-scale structures,” as used herein, refer to protuberances from the plane of the surface that the structure is on. The diameter of the protuberances is measured at the base of the structure. For non-symmetrical protuberances, the “diameter,” as used herein, refers to the longest distance across the base of the protuberance.

In some embodiments of the invention, the nanoscale structures have AFM-derived mean peak-to-valley heights in a range of 70 to 1000 nm, in some embodiments in a range of 70 to 500 nm, and in some embodiments, in a range of 70 to 150 nm. In some embodiments, the nanoscale structures are present on the implant at a high density. As used herein, a high density refers to a surface density in a range of 1 to 10 structures per square micrometer, 1 to 100 structures per square micrometer, 1 to 2500 structures per square micrometer, 1 to 10,000 structures per micrometer or 1 to 1,000,000 structures per square micrometer. In particular embodiments, the device implants have a surface density of 4 to 50 per square micrometer.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

### EXAMPLES

### Example 1

### cpTi, Grade 2

### Example 1a

### Preparation of Nanoscale Modified Surfaces

### Pre-Treatment of Titanium Disks

Ti disks with a diameter of 15 mm were punched from 1 mm thick sheets of grade 2 unalloyed Ti (ASTM F67 unalloyed Ti for surgical implant applications) and supplied by Institut Straumann AG (Basel, Switzerland). After degreasing the disks in acetone, the disks were exposed at 55° C. for 30 seconds to an aqueous solution consisting of 2% ammonium fluoride, 2% hydrofluoric acid and 10% nitric acid to generate “pre-treated” (PT) Ti disks. The PT disks were further sandblasted with corundum grit (0.25-0.50 μm) at 5 bar, followed by etching in a solution of hydrochloric and sulfuric acids heated above 100° C. for several minutes (proprietary process of Institut Straumann AG) to produce “sandblasted-large-grit-acid-etched” (SLA) disks. The samples were then rinsed with water and sterilized by gamma irradiation at 25 kGy overnight (≧12 h).

### Surface Modification

All PT and SLA disks were cleaned and sterilized before and after the NM treatment process. Prior to NM treatment, samples were cleaned using a protocol that involved two 15 minute sonication cycles each in detergent, ultra-pure water, acetone, isopropanol, ethanol, and then three 10 minute sonication cycles each in ultra-pure water, followed by plasma cleaning for 2 minutes at a maximum oxygen pressure of 0.27 mbar and at an RF power of 6.8 W (PDC-32G plasma cleaner, Harrick Plasma, Ithaca, N.Y.). The NM treatments consisted of exposure of the cleaned specimens at 740° C. to flowing (0.85 standard liters per minute) synthetic air (21% O₂, 79% N₂) at 1 atm for varied times. To evaluate the change in surface topography with exposure time, PT samples were treated for 45 minutes (NMPT45), 90 minutes (NMPT90), and 180 minutes (NMPT180). The development of nanoscale features on specimen surfaces was evaluated using scanning electron microscopy (SEM). The mass increase of the samples during such NM treatment was monitored via thermogravimetric (TG) analysis (Q50, TA Instruments, New Castle, Del.). After optimization of the NM treatment using PT samples, this treatment was applied to SLA samples. Prior to use in cell experiments, the NM-treated PT (NMPT) and NM-treated SLA (NMSLA) samples, and their respective unmodified controls, were cleaned by sonication in detergent and ultra-pure water and autoclave sterilized.

### Surface Characterization

The NMPT and NMSLA specimens were examined after sterilization by a variety of surface-sensitive techniques as described below.

Scanning Electron Microscopy (SEM)

The specimen surface topography was qualitatively evaluated using a field-emission-gun scanning electron microscope (Ultra 60 FEG-SEM, Carl Zeiss SMT Ltd., Cambridge, UK). Images were recorded using a 5 kV accelerating voltage and 30 μm aperture. Image analysis software (ImageJ, NIH software) was used to evaluate the dimensions of nanoscale structural features generated by the nanoscale modification treatment.

Transmission Electron Microscopy (TEM)

The thickness and crystal structure of the oxide layer formed upon NM treatment was evaluated using a field-emission-gun transmission electron microscope (HF-2000 FEG-TEM, Hitachi High Technologies America, Inc., Pleasanton, Calif.). The NMPT90 sample was embedded in epoxy, cross-sectioned, and then ground, polished, dimpled, and ion-milled to perforation. TEM characterization was then performed using an accelerating voltage of 200 KV.

Atomic Force Microscopy (AFM)

Surface measurements at the nanoscale were evaluated using atomic force microscopy (Nano-R AFM, Pacific Nanotechnology, Santa Clara, Calif.) in close-contact mode. AFM analyses were conducted using silicon probes (P-MAN-SICC-O, Agilent Technologies, Santa Clara, Calif.) with dimensions of 1.14×0.25 cm², a nominal force constant of 40 N/m, a nominal resonance frequency of 300 kHz, and tip radii of up to 10 nm. Each AFM analysis was performed over a 730 nm×730 nm area. Two samples of every group were scanned three times each, under ambient atmosphere. The original data was plane-leveled to remove tilt by applying a numerical second-order correction, and mean values of surface roughness (Sₐ) and peak-to-valley height (S_{z}) were determined using the NanoRule+ software (Pacific Nanotechnology).

Confocal Laser Microscopy (CLM)

Surface roughness at the macro- and micro-scales was evaluated using a confocal laser microscope (Lext, Olympus, Center Valley, Pa.). Each CLM analysis was performed over a 644 μm×644 μm area using a scan height step of 50 nm, a 20× objective, and a cutoff wavelength of 100 μm. Two samples of every group were scanned three times each, under ambient atmosphere. Mean values of surface roughness (Sₐ) and peak-to-valley height (S_{z}) were determined.

X-Ray Photoelectron Spectroscopy (XPS)

Atomic concentration and chemical bonding information were obtained from the specimen surfaces by X-ray photoelectron spectroscopy (Thermo K-Alpha XPS, Thermo Fisher Scientific, West Palm Beach, Fla.). The instrument was equipped with a monochromatic Al-Kα X-ray source (hv=1468.6 eV). The XPS analysis chamber was evacuated to a pressure of 5×10⁻⁸ mbar or lower before collecting XPS spectra. Spectra were collected using an X-ray spot size of 400 μm and pass energy of 100 eV, with 1 eV increments, at a 55° takeoff angle. Two samples of every group were scanned two times each.

Contact Angle Measurements

Contact angle measurements were obtained using a goniometer (CAM 100, KSV, Helsinki, Finland) equipped with a digital camera and image analysis software. Ultra-pure water was used as the wetting liquid, with a drop size of 5 μL. Sessile drop contact angles of the air-water-substrate interface were measured four times in two samples of every group.

X-Ray Diffraction (XRD)

X-ray diffraction analyses were conducted using 1.8 kW Cu Kα radiation, a 1° parallel plate collimator, a ¼ divergence slit, and a 0.04 rad soller slit (X'Pert PRO Alpha-1 diffractometer, PANalytical, Almelo, The Netherlands). Both Bragg-Brentano and θ-2θ parafocusing setups were used for regular and grazing-angle (i.e., 4° take-off angle) analyses, respectively. Two samples of every group were scanned two times each, under ambient atmosphere.

### Results of Surface Modification

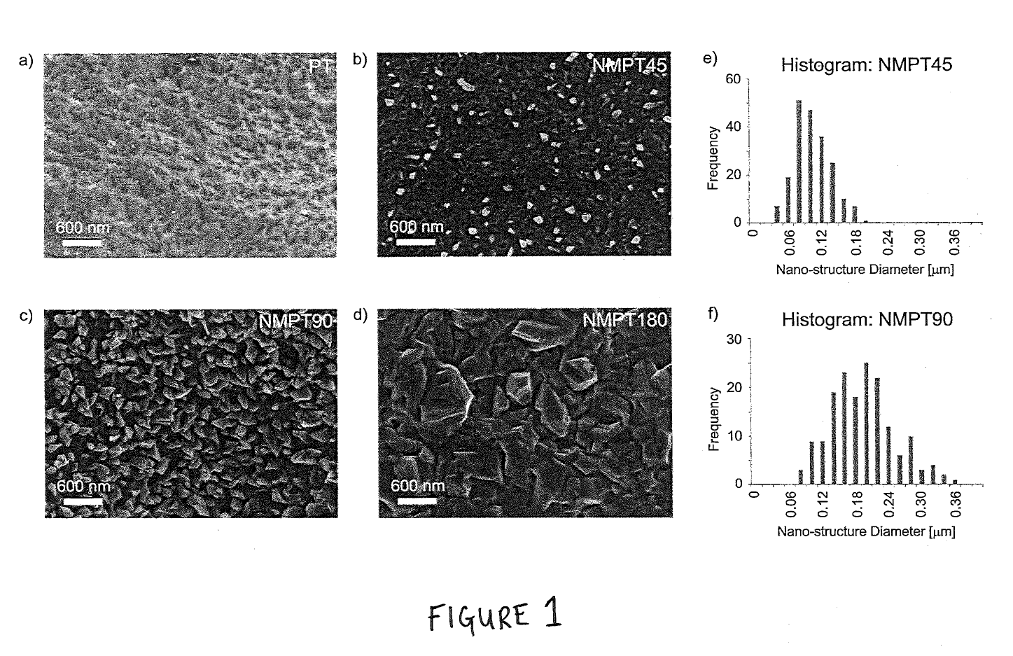

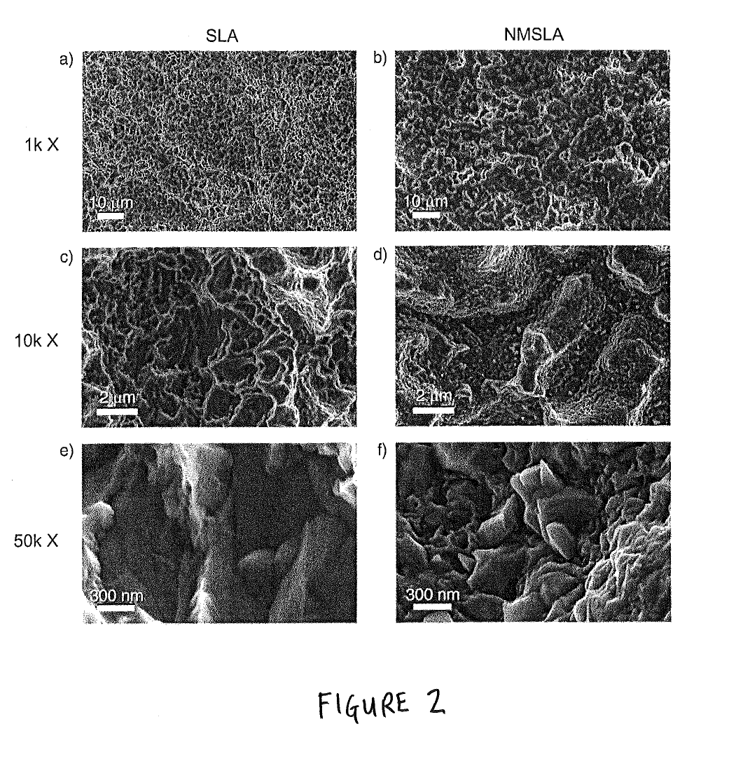

Scanning electron microscopy (FIGS. 1-3) confirmed that a modest temperature oxidation treatment could be used to introduce nanoscale structural features to the metal surfaces. In this study, the oxidation temperature (i.e., 740° C.) and gaseous environment (i.e., synthetic air) were fixed while the duration of the process was varied. The surfaces of the starting PT samples were relatively smooth on the microscale (CLM Sₐ=0.43±0.02 μm), although surface pits, presumably resulting from the PT acid pickling process, were detected (FIG. 1a). After 45 minutes of controlled oxidation (NMPT45), a low density of nanoscale protuberances was observed to have formed on the specimen surfaces (FIG. 1b), with protuberance sizes ranging from about 40 to 200 nm in diameter (FIG. 1e) and about 10 to 150 nm in height. After 90 minutes of modification (NMPT90), the entire surface was homogeneously covered with a relatively high density of nanoscale structures (FIG. 1e), which ranged in size from about 40 to 360 nm in diameter (FIG. 2f) and about 60 to 350 nm in height. Following 180 minutes of modification (NMPT180), the nanostructures coalesced into coarser structures (FIG. 1d) that spanned about 500 to 1000 nm in diameter and about 80 to 500 nm in height. The mass increase of the oxidized samples was also monitored by TG analyses and correlated to changes in surface topography. Indeed, by coupling weight gain measurements to the resulting surface topography, TG analyses were used to monitor the time required for the generation of a high surface density of nanoscale structures on titanium implants of various geometries.

The NM treatment was also applied to SLA substrates that possessed a greater degree of microscale roughness (CLM Sₐ=3.29±0.18 μm) than for the PT specimens. NMSLA samples were generated using the same oxidation conditions as for the NMPT90 samples (i.e., 740° C., 90 min, synthetic flowing air). At low magnifications (FIGS. 2a, b), SEM analyses revealed a similar microscale topography for the SLA and NMSLA samples. However, at intermediate and higher magnifications (FIGS. 2d, f), NMSLA surfaces were observed to possess a relatively high and uniform density of nanoscale structures.

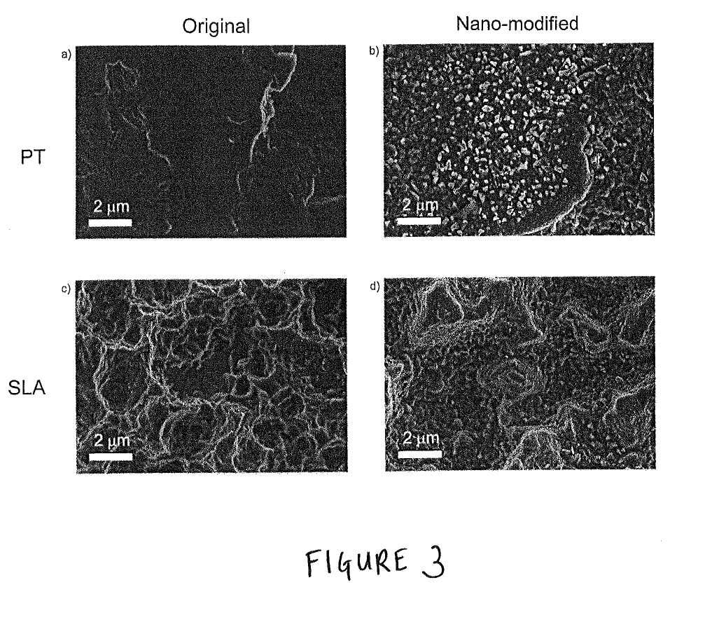

After verifying that a NM treatment (740° C., 90 min., synthetic flowing air) could be used to introduce a relatively high density of nanoscale structural features to Ti surfaces that were relatively smooth or rough at the microscale, this treatment was applied to Ti specimens for further surface characterization and for use in cell experiments. Cell interactions with four types of specimens were examined: PT (FIG. 3a), NMPT (FIG. 3b), SLA (FIG. 3c) and NMSLA (FIG. 3d). The microscale and nanoscale topography of these samples was measured quantitatively using CLM and AFM, respectively (Table 2). As expected, the mean values of microscale (CLM-derived) roughness and peak-to-valley height obtained for the PT and NMPT specimens were lower than for the SLA and NMSLA samples. Additionally, the average values of the microscale (CLM-derived) roughness of the nano-modified samples, NMPT and NMSLA, were slightly lower than for the respective controls. The mean nanoscale (AFM-derived) roughness of the NMPT specimens was apparently higher than for the PT controls (Table 2), although little statistical difference in the mean nanoscale roughness could be discerned between the SLA and NMSLA specimens. However, the NMPT and NMSLA surfaces shared noticeably higher (and similar) mean values of nanoscale peak-to-valley height relative to the PT and SLA surfaces. The combined CLM and AFM analyses were consistent with the presence of a relatively high density of nanoscale features on the NMPT and NMSLA specimens with little or no statistical change in the microscale topography.

TABLE 2
Mean ± one standard deviation (SD) values of roughness (Sₐ) and
peak-to-valley height (S_{z}) of the different titanium surfaces examined
using atomic force microscopy (AFM) and confocal laser microscopy (CLM).

| | AFM Mean | AFM Mean Peak-to- | CLM Mean | CLM Mean Peak-to- |
|---|---|---|---|---|
| | Roughness | Valley Height | Roughness | Valley Height |
| Sample | (Sₐ) ± 1 SD [nm] | (S_{z}) ± 1 SD [nm] | (Sₐ) ± 1 SD [μm] | (S_{z}) ± 1 SD [μm] |
| PT | —* | 58 ± 41 | 0.43 ± 0.02 | 7.99 ± 1.67 |
| NMPT | 16 ± 8 | 142 ± 69 | 0.37 ± 0.01 | 5.58 ± 0.35 |
| SLA | 14 ± 6 | 50 ± 22 | 3.29 ± 0.18 | 42.01 ± 4.02 |
| NMSLA | 18 ± 3 | 141 ± 80 | 2.80 ± 0.06 | 36.57 ± 2.00 |

*The mean roughness value was below the 10 nm detection limit of the AFM tip.

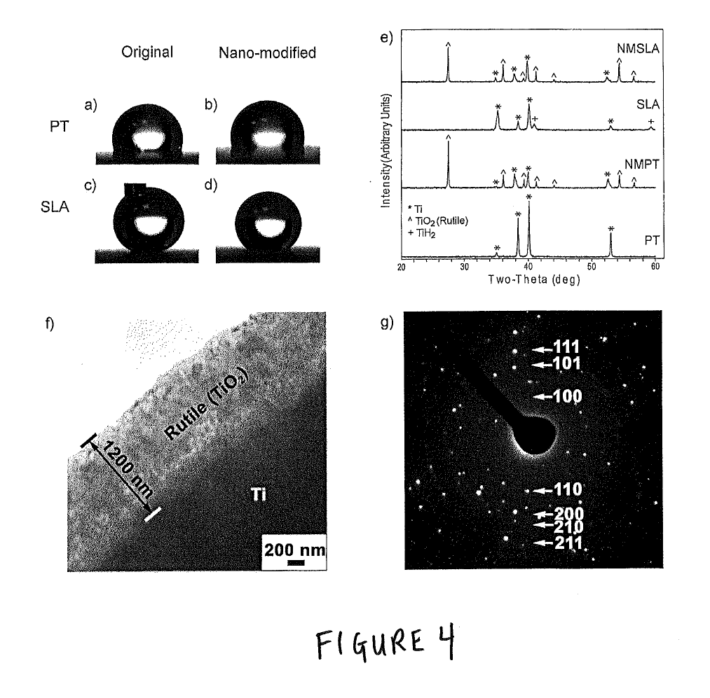

Water contact angle measurements indicated that all of the samples exhibited relatively hydrophobic behavior (FIGS. 4a-4d, Table 3). The contact angles measured for the SLA and NMSLA samples were significantly larger than for the PT and NMPT samples (FIGS. 4a-4d, Table 3), which was consistent with the enhanced mean values of microscale roughness (CLM-derived Sₐ values) and microscale peak-to-valley height (CLM-derived S_{z} values) for the SLA and NMSLA samples (Table 2).

TABLE 3
Mean values of water contact angle ± one standard deviation (SD).

| Sample | Contact Angle [° ± SD] |
|---|---|
| PT | 92 ± 1 |
| NMPT | 101 ± 0 |
| SLA | 157 ± 3 |
| NMSLA | 142 ± 1 |

General surveys of the surface chemistry of the different specimens by XPS analyses revealed the presence of appreciable oxygen and titanium. Within statistical error, the concentrations of oxygen and titanium on the PT and NMPT surfaces, and of oxygen and titanium on the SLA and NMSLA surfaces, were similar (Table 4). However, a detectable change in the phase content on the Ti surfaces after the NM treatment was revealed by XRD and TEM analyses (FIG. 4e, f). XRD analyses of the surfaces of the PT and SLA samples yielded major diffraction peaks for α-Ti (ICDD 01-089-3073) and did not yield detectable diffraction peaks for crystalline oxides of titanium (FIG. 4e). The SLA samples also exhibited additional diffraction peaks of modest intensity that were attributed to titanium hydride (TiH₂, ICDD 04-008-1386). Both NMPT and NMSLA specimens exhibited relatively intense diffraction peaks for the rutile polymorph of TiO₂ (ICDD 01-071-6411). The α-Ti diffraction peaks in the NM-treated samples also appeared to shift to lower two-theta values. TEM analysis of an ion-milled cross-section of the NMPT sample (FIG. 4f) revealed the presence of a compact and conformal oxide layer on the Ti surface. The average thickness of this oxide layer, generated within 90 min at 740° C. in air, was about 1.2 μm. Selected area electron diffraction (SAED) analysis (FIG. 4g) of this oxide scale yielded a diffraction pattern that was consistent with the presence of only the rutile polymorph of TiO₂ (as had also been revealed by the XRD analyses of NM-treated specimens).

TABLE 4
Mean values of NMPT/PT and NMSLA/SLA O and Ti concentration
ratios ± one standard deviation (SD) as determined
by x-ray photoelectron spectroscopy (XPS).

| | Mean Ratios of Elemental Concentrations ± 1 SD | |
|---|---|---|
| Sample | O | Ti |
| NMPT/PT | 0.97 ± 0.23 | 0.89 + 0.20 |
| NMSLA/SLA | 1.24 ± 0.07 | 1.29 + 0.13 |

### Example 1b

### Cell Culture Model and Assays

MG63 cells were obtained from the American Type Culture Collection (Rockville, Md.) and were cultured in Dulbecco's modified Eagle medium, containing 10% fetal bovine serum (FBS) and 1% penicillin and streptomycin, at 37° C. in an atmosphere of 5% CO₂ and 100% humidity. Cells were grown on tissue culture polystyrene (TCPS) or on one of the four types of specimens (PT, NMPT, SLA, NMSLA) at a density of 10,000 cells/cm². MG63 cells were fed 24 hours after they were plated on the different surfaces and every 48 hours until confluent, as evaluated on the TCPS substrate. At confluence, cells were treated with fresh media for 24 hours and harvested for assays. At harvest, conditioned media were collected and cell layers were washed twice with serum-free media to remove any non-adherent cells, followed by two sequential incubations in 500 μL of 0.25% trypsin for 10 minutes at 37° C. to release the cells from their substrate. The trypsin reaction was terminated by adding FBS-containing media to the tubes and cells were then centrifuged at 2000 rpm for 15 minutes. The supernatant was decanted, and the cell pellets were resuspended by vortexing in 500 μL of 0.05% Triton-X-100. The cells were then lysed to release cell contents.

Cell proliferation was evaluated by measuring DNA content with a commercially-available kit (Quant-iT™ PicoGreen® dsDNA assay, Invitrogen, Carlsbad, Calif.). Cells were harvested as described above and 50 μL of lysed cell content were diluted with 50 μL of 0.05% Triton-X-100. Fluorescence measurements were obtained using a fluorescent multimode detector (DTX880, Beckman Coulter, Brea, Calif.) with reference to a standard.

Cell differentiation was evaluated using two markers of osteoblast differentiation: cellular alkaline phosphatase-specific activity [orthophosphoric monoester phosphohydrolase, alkaline; E.C. 3.1.3.1] as an early differentiation marker; and osteocalcin content in the conditioned media as a late differentiation marker. Alkaline phosphatase activity was assayed from the release of p-nitrophenol from p-nitrophenylphosphate at pH 10.2 as previously described [47]. Activity values were normalized to the protein content, which was detected as colorimetric cuprous cations in biuret reaction (BCA Protein Assay Kit, Pierce Biotechnology Inc., Rockford, Ill., USA) at 570 nm (Microplate reader, BioRad Laboratories Inc., Hercules, Calif., USA). Osteocalcin levels in the conditioned media were measured using a commercially available radioimmunoassay kit (Human Osteocalcin RIA Kit, Biomedical Technologies, Stoughton, Mass.). Briefly, 50 μL of conditioned media were mixed with [I-125] osteocalcin tracer and human osteocalcin anti-serum (100 μL each), and incubated at 37° C. for 2.5 hours. Goat anti-rabbit IgG, polyethylene glycol (100 μL each), and 1 mL of PBS were then added, followed by centrifugation at a minimum of 1500×g for 15 minutes at 4° C. The supernatant was decanted and the pellets were counted for 1 minute in a LS1500 gamma counter (Beckman Coulter, Brea, Calif.).

The conditioned media were also assayed for protein levels of growth factors and cytokines. Osteoprotegerin (OPG), a cytokine that works as a decoy receptor for “receptor activator for nuclear factor κ B ligand” (RANKL) to inhibit osteoclastogenesis, was measured using enzyme-linked immunosorbent assay (ELISA) kits (DY805 Osteoprotegerin Duo Set, R&D Systems, Minneapolis, Minn.), Vascular endothelial growth factor (VEGF), a potent growth factor involved in vasculogenesis and angiogenesis, was also measured using an enzyme-linked immunosorbent assay (ELISA) kit (DY293B VEGF DuoSet, R&D Systems).

Results from Cell Culture Assay

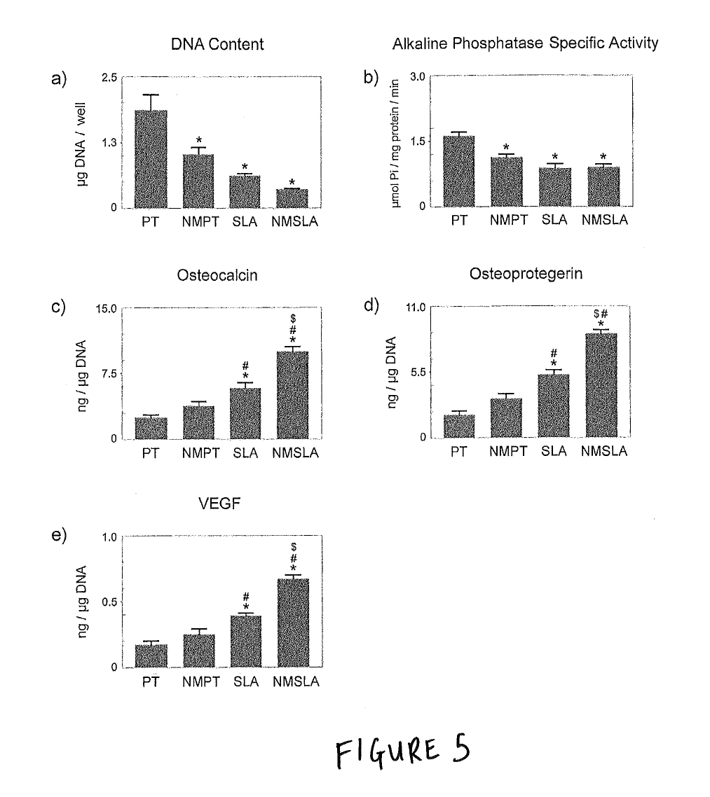

Osteoblasts were sensitive to the surface modifications. The number of MG63 osteoblast cells, as deduced from DNA measurements (FIG. 5a), and the alkaline phosphatase specific activity (FIG. 5b) for the NMPT, SLA, and NMSLA samples were statistically lower than for the PT specimens. This reduction in cell content and ALP activity paralleled an increase in mean nanoscale roughness (NMPT vs. PT) and the microscale roughness (SLA and NMSLA vs. PT). While the levels of osteocalcin, osteoprotegerin, and vascular endothelial growth factor (FIGS. 5c-e) measured for the PT and NMPT samples were not noticeably different, statistically-significant increases in the levels of these markers were observed for the SLA specimens, which paralleled the increase in microscale roughness for the SLA specimens relative to the PT and NMPT samples (Table 2). Further statistically significant increases in the osteocalcin, osteoprotegerin, and VEGF levels over the SLA specimens was observed for the NMSLA specimens.

### Statistical Analysis

Data from experiments characterizing the surface properties of the substrates are presented as the mean±one standard deviation (SD) of all the measurements performed on different samples. Data from experiments examining cell response are presented as mean±standard error (SE) for six independent cultures. All experiments were repeated at least twice to ensure validity of the observations and results from individual experiments are shown. Data were evaluated by analysis of variance, and significant differences between groups were determined using Bonferroni's modification of Student's t-test. A p value below 0.05 was considered to indicate a statistically-significant difference.

As can be seen from the data shown above, a simple and scalable process for achieving a homogenous and relatively high surface density of nanoscale structures on titanium metal surfaces was developed. An additional attribute of the surface modification process is that it does not require a straight line path to modify or superimpose the nanoscale structures on the surface (non-line-of-sight). The process resulted in the superimposition of a high density of nanoscale structures on Ti substrates (as revealed by SEM and AFM analyses) in the absence or presence of appreciable microscale roughness. This nanoscale modification treatment did not affect surface chemistry (as revealed by XPS measurements) or wettability (as revealed by water contact angle measurements), and did change surface crystal structure (as revealed by XRD and TEM analyses). Moreover, osteoblast behavior was sensitive to the modified surfaces.

The development of this oxidation-based modification process involved correlation of the changes in surface topography and weight of Ti disks with the duration of oxidation in synthetic air at 740° C. Two types of Ti specimens were examined; pretreated specimens, and large-grit sandblasted and acid-etched specimens. As expected, confocal laser microscopy measurements indicated that the microscale surface roughness of the SLA specimens was significantly enhanced relative to the PT specimens. SEM analyses revealed the formation of nanoscale structures on the specimen surfaces upon oxidation at 740° C. for times between 45 and 180 min. With an increase in oxidation time, the surface density and average sizes of nanoscale structures formed on this scale increased. After 90 min, a relatively high density of such structures was observed to have formed uniformly over the specimen surfaces, with the SEM-derived diameters and heights ranging from about 40 to 360 nm and about 60 to 350 nm respectively. It is interesting to note that the nanostructures formed by the present oxidation-based process are not unlike the nanostructures associated with collagen fibrils left by osteoclasts after bone resorption. The average values of the CLM-derived microscale roughness (Sₐ) and the peak-to-valley height (S_{z}) for the nano-modified samples were slightly lower than for the respective controls. At least one contribution to such modest reductions in the average Sₐ and S_{z} values was likely to have been the formation of the 1.2 μm-thick oxide scale. AFM measurements revealed a significant increase in the mean nanoscale surface roughness, and mean peak-to-valley height, after exposure of PT samples to this 740° C./90 min oxidation treatment. While a statistically-significant increase in the mean nanoscale roughness could not be detected after exposure of SLA specimens to this 740° C./90 min treatment, a significant increase in the mean peak-to-valley height was detected.

XPS analyses indicated that exposure of the PT and SLA specimens to the 740° C./90 min treatment did not greatly affect the concentration of titanium and oxygen on the surfaces of these specimens, which was not surprising due to the presence of a native titanium oxide layer on both original and modified samples. The water contact angles on the PT and SLA samples also did not appreciably change after the 740° C./90 min oxidation treatment. However, XRD and TEM analyses revealed that this treatment resulted in the formation of a compact and conformal rutile TiO₂ scale of about 1.2 microns thickness. Noticeable shifts in the two-theta positions of α-Ti diffraction peaks were also detected in the modified samples, which was consistent with an expansion of the α-Ti lattice associated with the incorporation of oxygen (note: the solubility of oxygen in α-Ti at 740° C. is 33.3 at %).

A high density of nanoscale structures, as well as the presence of appreciable microscale roughness, affected the proliferation of MG63 cells. The number of MG63 osteoblast cells detected on the nano-modified PT (NMPT) samples was lower than for the starting PT specimens. Similarly, cell numbers on SLA and nanoscale-modified SLA (NMSLA) samples were lower than on the PT specimens.

Osteoblast differentiation was greatly enhanced on surfaces that possessed both microscale roughness and a high density of nanoscale features. These results are in agreement with previous studies, which have indicated that a combination of nanoscale features and microscale roughness are required to achieve an additive, if not synergistic increase, in osteoblast differentiation. In Example 1b, ALP activity was reduced and osteocalcin production was increased in a surface micro-roughness and nanostructure density dependent manner. Other studies reported larger ALP stained areas and higher ALP activity as well as higher osteocalcin gene expression for osteoblasts grown on micro-/nano-structured surfaces. Differences in ALP activity between the present results and those of other studies could be due to the biphasic nature of ALP, which has been shown to increase at the early stages of osteoblast differentiation followed by a decrease in activity when more mature osteoblasts start producing osteocalcin just before mineralization.

The cells growing on the NMSLA surfaces also produced significantly higher levels of the local factor osteoprotegerin, which inhibits osteoclastogenesis, and VEGF, which is a potent angiogenic factor. Taken together with the DNA, ALP, and osteocalcin measurements, these results suggest that the combined superimposition of a high density of nanoscale structures with a surface possessing appreciable micro-/submicro-scale roughness may promote bone formation directly in contact with the surface as well as in the surrounding tissue, thereby improving implant osseointegration.

### Example 2

### cpTi, Grade 2 (Different Temperatures)

### Pre-Treatment of Titanium Surface

Ti disks with a diameter of 15 mm were punched from 1 mm thick sheets of grade 2 unalloyed Ti (ASTM F67 unalloyed Ti for surgical implant applications) and supplied by Institut Straumann AG (Basel, Switzerland). After degreasing the disks in acetone, the disks were exposed at 55° C. for 30 seconds to an aqueous solution consisting of 2% ammonium fluoride, 2% hydrofluoric acid and 10% nitric acid to generate “pre-treated” (PT) Ti disks. The samples were then rinsed with water and sterilized by gamma irradiation at 251 Gy overnight (≧12 h).

### Surface Modification

All PT disks were cleaned and sterilized before and after the NM treatment process. Prior to NM treatment, samples were cleaned using a protocol that involved two 15 minute sonication cycles each in detergent, ultra-pure water, acetone, isopropanol, ethanol, and then three 10 minute sonication cycles each in ultra-pure water, followed by plasma cleaning for 2 minutes at a maximum oxygen pressure of 0.27 mbar and at an RF power of 6.8 W (PDC-32G plasma cleaner, Harrick Plasma, Ithaca, N.Y.). The NM treatments consisted of exposure of the cleaned specimens at different temperatures (i.e., 690° C., 740° C. and 800° C.) to flowing (0.85 standard liters per minute) ultra-pure nitrogen (99.999% N₂, 0.001% O₂) at 1 atm for 8 hours. To evaluate the change in surface topography with exposure temperature, PT samples were treated at 690° C. (NMPT-690C), 740° C. (NMPT-740C), and 800° C. (NMPT-800C).

### Results of Surface Modification

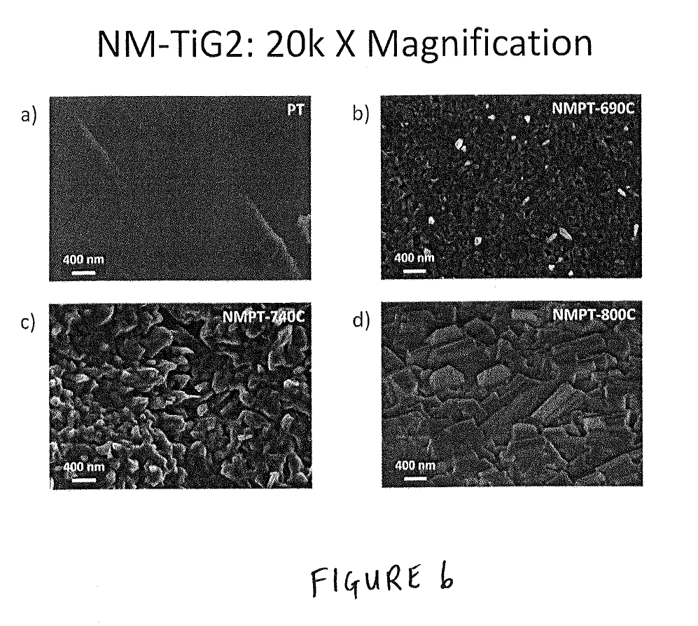

Referring to FIG. 6, the PT titanium samples (FIG. 6a) that were relatively smooth (Ra<0.5 μm) were exposed to a reactive gas of 99.999% N₂/0.001% O₂ for 8 hours at various temperatures: 690° C. (FIG. 6b), 740° C. (FIG. 6c) and 840° C. (FIG. 6d). The different temperatures affected the final roughness of the sample at the nanoscale level and also changed the final shape of the structures on the surface. The modification seemed to follow a similar trend than when the temperature and the environment were fixed, using higher concentrations of O₂. At lower temperatures (i.e., 690° C.) the presentation of nano-structures on the surface had low surface coverage, which increased at higher temperatures (i.e., 740° C.). However, after a certain temperature (i.e., 800° C.) the structures' growth-kinetics were faster to the point where they started coalescing and forming bigger structures for the respective modification time.

### Example 3

### cpTi, Grade 4

### Pre-Treatment of Titanium Surface

Ti disks of 1 mm thickness were cut from rod stocks (Ø=5 mm) of grade 4 unalloyed Ti (ASTM F67 unalloyed Ti for surgical implant applications) and supplied by Institut Straumann AG (Basel, Switzerland). After degreasing the disks in acetone, the disks were exposed at 55° C. for 30 seconds to an aqueous solution consisting of 2% ammonium fluoride, 2% hydrofluoric acid and 10% nitric acid to generate “pre-treated” (PTG4) Ti disks. The samples were then rinsed with water and sterilized by gamma irradiation at 251 Gy overnight (≧12 h).

### Surface Modification

The NM treatments consisted of exposure of the Ti grade 4 specimens at 740° C. to flowing (0.85 standard liters per minute) synthetic air (21% O₂, 79% N₂) at 1 atm for varied times. To evaluate the change in surface topography with exposure time, PTG4 samples were treated for 45 minutes (NMPTG4-45m), 90 minutes (NMPTG4-90m), and 180 minutes (NMPTG4-180m).

The development of nanoscale features on specimen surfaces was evaluated using scanning electron microscopy (SEM). Prior to characterization, the NM-treated PTG4 samples (NMPT), and their respective unmodified controls, were cleaned by sonication in detergent and ultra-pure water and autoclave sterilized.

### Results of Surface Modification

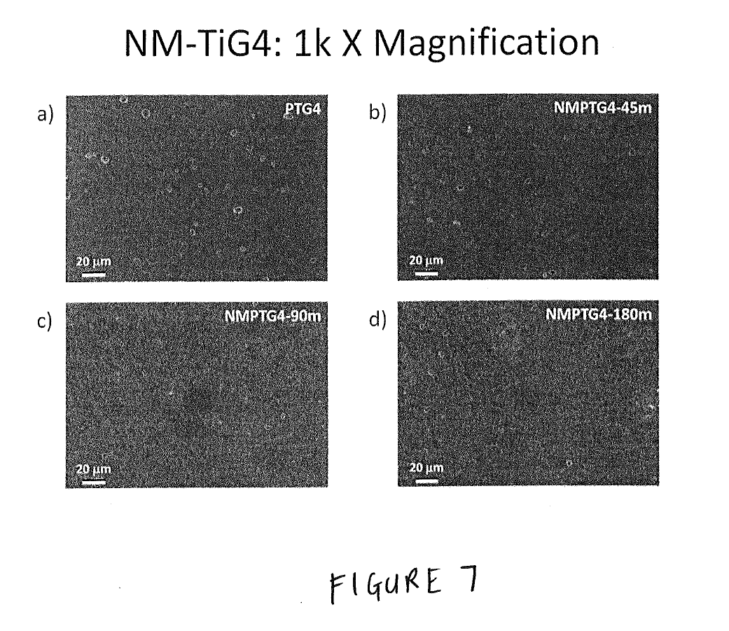

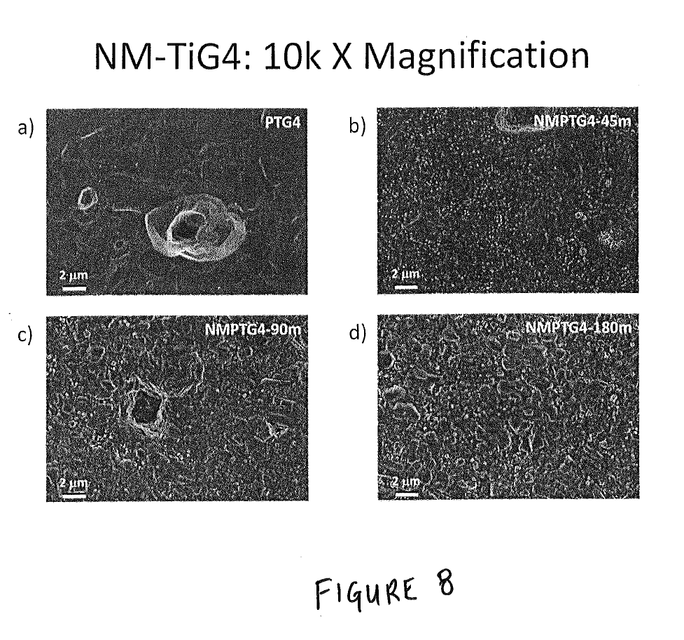

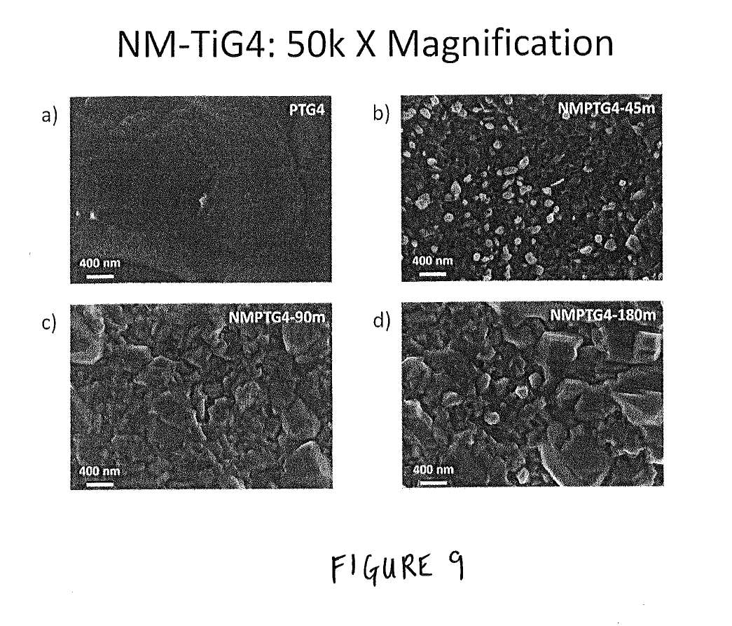

SEM images were used to evaluate the similarities and differences between PTG4 and NMPTG4 samples (FIG. 7). At low magnifications, the surface of the original PTG4 samples was relatively smooth with no distinct features except for some apparent grain boundaries and several holes that looked like missing grains (FIG. 7a). The surfaces of all the NMPTG4 samples were very similar to the original PTG4 sample, with the holes left by missing grains still evident (FIG. 7b, c, d). At mid-magnifications, the NMPTG4-45m sample (FIG. 8b) had higher surface coverage of nano-structures than the rest of the NMPTG4 modified for 90 (FIG. 8c) and 180 minutes (FIG. 8d), which had shallower holes and the presence of bigger structures possibly resulting from the coalescence of the nano-structures after prolonged modification times. At higher magnifications (FIGS. 9a-9d), the nano-structures on the NMPTG4-45m sample were found to be in the size range of 20 to 150 nm in diameter and 10 to 300 nm in height (FIG. 9b).

These results demonstrate the ability of the nano-modification process to superimpose a homogenous surface coverage of nano-structures on the surface of commercially pure titanium grade 4, which is the grade usually used for implant applications due to its desirable mechanical properties.

### Example 4

### Ti Alloy (i.e., Ti₆Al₄V)

### Pre-Treatment of Ti Alloy Surface

Titanium alloy (Ti₆Al₄V) disks were used in this study. The disks were 15 mm in diameter to fit snuggly in a well of a twenty-four-well culture plate. To create a roughened surface texture (rTiAlV), TiAlV disks were machined, treated with a proprietary etch process, and passivated.

### Surface Modification

The nano-modification (NM) treatments consisted of exposure of the Ti alloy specimens at 740° C. to flowing (0.85 standard liters per minute) synthetic air (21% O₂, 79% N₂) at 1 atm for varied times. To evaluate the change in surface topography with exposure time, rTiAlV samples were treated for 45 minutes (rTiAlV-45m), 90 minutes (rTiAlV-90m), and 180 minutes (rTiAlV-180m). Before use in cell culture studies, all disks were ultrasonically cleaned in 2% microsoap (Micro-90, Int. Products Corp., Burlington, N.J.) and ultrapure water (Millipore, Billerica, Mass.), and sterilized by autoclave (Tuttnauer, Hauppauge, N.Y.) for 20 minutes at 121° C. and 15 PSI.

### Surface Characterization

The surface topography was qualitatively evaluated using a field-emission-gun scanning electron microscope (Ultra 60 FEG-SEM, Carl Zeiss SMT Ltd., Cambridge, UK). SEM images were recorded using a 5 kV accelerating voltage and 30 μm aperture. Surface roughness was quantitatively analyzed using a confocal laser microscope (OLS4000 CLM, Lext, Olympus, Center Valley, Pa.). Each CLM analysis was performed over a 644 μm×644 area using a scan height step of 50 nm, a 20× objective, and a cutoff wavelength of 100 μm to determine the mean values of surface roughness (Sₐ) Atomic concentration close to the surface was obtained by energy dispersive X-ray spectroscopy (INCAx-act EDX, Oxford Instruments, Concord, Mass.). EDX spectra were collected using a magnification of 500× and a working distance of 10 mm. Contact angle measurements were obtained using a goniometer (CAM 100, KSV, Helsinki, Finland) equipped with a digital camera and image analysis software. Ultra-pure water was used as the wetting liquid, with a drop size of 5 μL.

### Results of Surface Modification

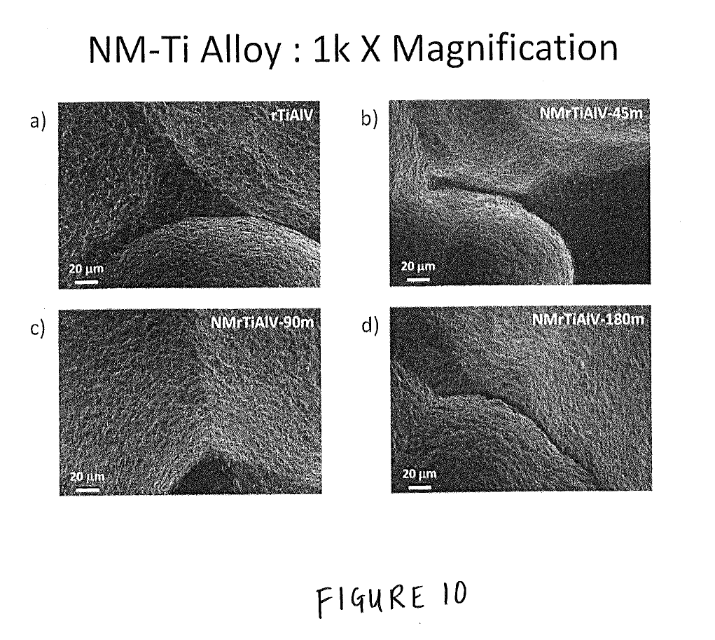

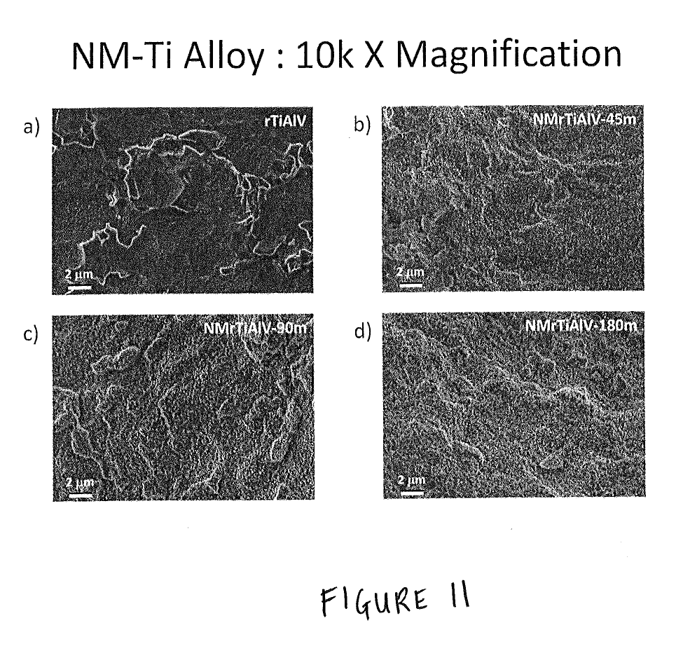

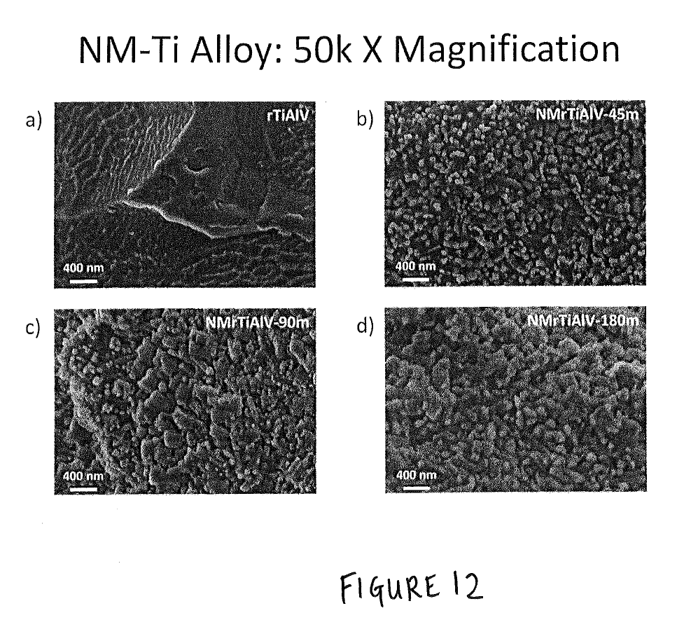

Images of the surfaces, acquired by scanning electron microscopy (SEM), revealed the different topographies of the samples (FIG. 10). The rTiAlV surface presented 100-300 μm craters with superimposed micron-scale features (FIG. 10a). All the nano-modified surfaces maintained a similar macro- to micro-scale structure (FIG. 10b, c, d). At mid-magnifications, the micron-scale features could be more easily distinguished in all samples (FIG. 11), and in the case of the rTiAlV sample these features resembled small terraces with faint submicron-scale texture (FIG. 11a). However, the SEM images of the nano-modified surfaces also revealed an additional nano-texture that homogeneously covered the entire surface (FIG. 11b, c, d). At very high magnifications, again the rTiAlV sample showed no distinct features except for some minor ridges and dips on the surface (FIG. 12a). At this magnification, a difference could be distinguished between the different modification times. The NMrTiAlV-45m sample had very well defined nano-structures with a size of 20 to 150 nm in diameter and 10 to 300 nm in height (FIG. 12b). However, although samples modified for 90 (FIG. 12c) and 180 minutes (FIG. 12d) had similar nano-structures, these started coalescing and forming bigger aggregates.

The surface roughness was quantitatively analyzed by confocal laser microscopy (Table 5), which probes the surface at the macro- and micro-scale level. Confirming the qualitative evaluation by SEM, there were no significant differences in the macro- to micro-scale roughness between the rTiAlV surface and the nano-modified versions.

TABLE 5
Mean values of roughness (Sₐ) and peak-to-valley height
(S_{z}) ± one standard deviation (SD) of the different titanium
alloy surfaces examined using confocal laser microscopy (CLM).

| | CLM Roughness | CLM Peak-to- |
|---|---|---|
| | Average | Valley Height |
| Sample | (Sₐ) [μm] | (S_{z}) [μm] |
| rTiAlV | 1.81 ± 0.51 | 53.26 ± 19.19 |
| NMrTiAlV-45 m | 2.04 ± 0.16 | 43.48 ± 2.52 |
| NMrTiAlV-90 m | 1.96 ± 0.24 | 41.62 ± 4.61 |
| NMrTiAlV-180 m | 2.01 ± 0.52 | 39.15 ± 16.19 |

Chemical analysis of the different samples performed by EDX (Table 6) and XPS (Table 7) showed a clear distinction in chemical composition between the rTiAlV sample and the nano-modified samples. The EDX spectrum of the rTiAlV sample showed the presence of Ti, Al and V in concentrations similar to the bulk chemistry of the alloy, whereas the nano-modified samples were mainly composed of O, in addition to Ti, Al and V. This O content is probably coming from the growth of the oxide layer on the surface after the heat treatment. The XPS spectra of the different samples also showed marked differences in the presentation of the main elements on the surface. The rTiAlV sample had large concentrations of C, O and Ti on the surface, with smaller concentrations of Al, N, Si and in some cases V. The nano-modified samples, however, all had large concentrations of O and Al on the surface, with the C content almost reduced in half. These samples also had lower concentrations of Ti and N, with no evidence of Si or V on the surface.

TABLE 6
Atomic concentrations ± one standard deviation (SD) of Ti alloy samples
as determined by energy-dispersive X-ray spectroscopy (EDX).
Elemental composition of Ti disk analyzed by EDX

| | Concentration [Atomic % ± SD] | | | |
|---|---|---|---|---|
| Sample | O | Ti | Al | V |
| rTiAlV | — | 85.7 ± 1.1 | 10.9 ± 1.1 | 3.3 ± 0.0 |
| NMrTiAlV-45 m | 69.2 ± 0.7 | 25.1 ± 0.7 | 4.5 ± 0.1 | 1.2 ± 0.1 |

TABLE 7
Atomic concentrations ± one standard deviation (SD) of Ti alloy samples
as determined by X-ray photoelectron spectroscopy (XPS).
Elemental composition of Ti disk surfaces analyzed by XPS

| | Concentration [Atomic % ± S.D.] | | | | | | |
|---|---|---|---|---|---|---|---|
| Sample | O | Ti | N | C | Si | Al | V |
| rTiAlV¹ | 37.4 ± 2.5 | 10.5 ± 1.1 | 2.2 ± 0.3 | 42.5 ± 2.6 | 3.0 ± 0.5 | 2.9 ± 0.7 | 5.7 ± 7.3 |
| NMrTiAlV-45 m | 52.2 ± 1.0 | 7.0 ± 0.4 | — | 18.4 ± 1.6 | — | 22.4 ± 0.3 | — |
| NMrTiAlV-90 m | 49.4 ± 0.5 | 5.8 ± 0.0 | 1.6 ± 0.2 | 19.9 ± 0.3 | — | 23.2 ± 0.7 | — |
| NMrTiAlV-180 m | 49.3 ± 0.3 | 5.9 ± 0.1 | 1.2 ± 0.2 | 20.8 ± 1.1 | — | 22.7 ± 1.5 | — |

¹rTiAlV disks presented traces of: Ca, Cl

Surface wettability assessed by contact angle measurements (Table 7) revealed that the nano-modification process was able to reduce the water contact angle of the rTiAlV samples after just 45 minutes of modification. Additionally, after 90 minutes of modification the water contact angle was decrease even further.

TABLE 8
Mean values of water contact angle ± one standard deviation (SD).

| Sample | Contact Angle (°) ± S.D. |
|---|---|
| rTiAlV | 85 ± 7 |
| NMrTiAlV-45 m | 40 ± 4 |
| NMrTiAlV-90 m | 24 ± 1 |

The results of the surface characterization of the rTiAlV samples and the nano-modified groups using durations of 45, 90 and 180 minutes demonstrate that the nano-modification process developed by our group can be applied to other metals besides commercially pure titanium.

1. A method of manufacturing an implant device, comprising
exposing a surface of the implant device to a reactive gas at a temperature in a range of 500 to 1000° C., wherein the reactive gas comprises a reactive species and, optionally, an inert gas, for a duration sufficient to generate a high density of nanoscale structures on the exposed surface of the device.

2. The method of claim 1, wherein the implant device is exposed to the reactive gas at a temperature in a range of 500 to 1000° C. for a time in a range of 0.25 to 8 hours.

3. The method of claim 1, wherein the mean peak to valley height of the nanoscale structures is in a range of 70 to 500 nm.

4. The method of claim 3, wherein the mean peak to valley height of the nanoscale structures is in a range of 70 to 150 nm.

5. The method of claim 1, wherein the density of the nanoscale structures is in a range of 1 to 1000 structures per square micrometer.

6. The method of claim 5, wherein the density of the nanoscale structures is in a range of 4 to 50 structures per square micrometer.

7. The method of claim 1, wherein the reactive species comprises oxygen, hydrogen, nitrogen, sulfur and/or carbon.

8.-9. (canceled)

10. The method of claim 1, wherein the reactive species is present in the reactive gas at a partial pressure in a range of 7×10⁻⁶⁴ to 1 atm.

11. The method of claim 1, wherein the reactive species is present in the reactive gas at a partial pressure in a range of 0.1 to 1 atm.

12. The method of claim 1, wherein the surface of the implant device is pre-treated prior to exposure to the reactive gas.

13. The method of claim 12, wherein the implant device is pre-treated by one or more of the processes selected from the group consisting of sand blasting, grit blasting, acid etching and machining.

14. The method of claim 1, wherein the implant device is a metallic implant device and the reactive species is oxygen gas.

15. The method of claim 14, wherein the metallic implant device comprises titanium metal or a titanium alloy.

16. (canceled)

17. The method of claim 15, wherein the titanium alloy comprises Ti₆Al₄V.

18. The method of claim 1, wherein the implant device comprises a ceramic implant device and the reactive species is hydrogen gas.

19. The method of claim 18, wherein the ceramic implant device comprises titanium dioxide.

20. The method of claim 1, wherein the reactive species is oxygen and is present in the reactive gas at a concentration of 0.1-25%, and wherein the implant device comprises titanium and is exposed to the reactive gas at a temperature is in a range of 650 to 800° C.

21. The method of claim 1, wherein the implant device comprises nanostructures having a diameter in a range of 20 to 500 nm and a height in a range of 60 to 800 nm.

22. An implant device formed by the method of claim 1.

23. An implant device comprising
microscale structures on a surface of the device, wherein the microscale structures have diameters in a range of 1 and 100 μm and heights in a range of 1 to 50 μm; and
nanoscale structures on the surface of the device, wherein the nanoscale structures have diameters in a range of 20 to 500 nm and heights in a range of 60 to 800 nm.

24. The implant device of claim 23, wherein the implant comprises titanium or a titanium alloy.

25. The implant device of claim 23, wherein the implant comprises a ceramic.

26. The implant device of claim 23, wherein the density of the nanoscale structures is in a range of 4 to 50 structures per square micrometer.

27. The implant device of claim 23, wherein the valley to peak ratio is in a range of 70 to 500 nm.
